(19) United States
(12) Patent Application Publication
(10) Pub. No.: US 2025/0285979 A1
(43) Pub. Date: Sep. 11, 2025

(54) SEMICONDUCTOR DEVICE

(71) Applicant: Samsung Electronics Co., Ltd., Suwon-si (KR)

(72) Inventors: Sang Hoon Ahn, Suwon-si (KR); Jong Hwan Park, Suwon-si (KR); Bong Jin Kuh, Suwon-si (KR); Jang-Hee Lee, Suwon-si (KR)

(21) Appl. No.: 18/923,806

(22) Filed: Oct. 23, 2024

(30) Foreign Application Priority Data
Mar. 11, 2024 (KR) 10-2024-0033656

(51) Int. Cl. H01L 23/535; H01L 21/768

(52) U.S. Cl. CPC H01L 23/535; H01L 21/76805; H01L 21/76895

(57) ABSTRACT

A semiconductor package includes first and second wiring patterns on a substrate and spaced laterally from one another, a first interlayer insulating layer on the substrate and surrounding a sidewall of each of the first and second wiring patterns, the first interlayer insulating layer including a first material having a first dielectric constant, a second interlayer insulating layer on the first interlayer insulating layer, at least a portion of the second interlayer insulating layer overlapping the first and second wiring patterns, the second interlayer insulating layer including a second material having a second dielectric constant greater than the first dielectric constant, a third interlayer insulating layer on the second interlayer insulating layer, and a via extending vertically in the third interlayer insulating layer and connected to the first wiring pattern. Each of the first and second interlayer insulating layers does not overlap each of the first and second wiring patterns.

### CROSS-REFERENCE TO RELATED APPLICATION

This application claims priority from Korean Patent Application No. 10-2024-0033656 filed on Mar. 11, 2024 in the Korean Intellectual Property Office, and all the benefits accruing therefrom under 35 U.S.C. § 119, the contents of which in its entirety are herein incorporated by reference.

### BACKGROUND

### Technical Field

The present disclosure relates generally to a semiconductor device.

### Description of Related Art

Due to the development of electronic technology, down-scaling of a semiconductor device has recently progressed rapidly, thereby requiring high integration and low power consumption of a semiconductor chip. A pitch between circuit components such as wiring patterns is gradually decreasing. In a follow-up process such as a chemical mechanical planarization/polishing (CMP) process and an etching process, damage to an interlayer insulating layer formed between the wiring patterns may occur. Therefore, research is underway to solve this problem.

### SUMMARY

A purpose of the present disclosure is to provide a semiconductor device in which between adjacent ones of a plurality of wiring patterns, an upper interlayer insulating layer with a high dielectric constant and a high density is formed on a lower interlayer insulating layer with a low dielectric constant and a low density, such that damage to the lower interlayer insulating layer is prevented (or at least reduced) while a subsequent process such as a planarization process (CMP process) and an etching process is performed.

According to some embodiments of the present disclosure, there is provided a semiconductor device, comprising a substrate, a first wiring pattern on an upper surface of the substrate, a second wiring pattern on the upper surface of the substrate, the second wiring pattern spaced apart from the first wiring pattern in a horizontal direction, a first interlayer insulating layer surrounding a sidewall of each of the first and second wiring patterns on the upper surface of the substrate, the first interlayer insulating layer including a first material having a first dielectric constant, a second interlayer insulating layer being in contact with an upper surface of the first interlayer insulating layer, at least a portion of the second interlayer insulating layer overlapping each of the first and second wiring patterns in the horizontal direction, the second interlayer insulating layer including a second material having a second dielectric constant greater than the first dielectric constant, a third interlayer insulating layer disposed on an upper surface of the second interlayer insulating layer, and a via penetrating (i.e., extending in) the third interlayer insulating layer in a vertical direction, the via connected to the first wiring pattern, wherein each of the first and second interlayer insulating layers non-overlaps each of the first and second wiring patterns in the vertical direction.

According to some embodiments of the present disclosure, there is provided a semiconductor device, comprising a substrate, first to third wiring patterns sequentially spaced apart from each other in a horizontal direction on an upper surface of the substrate, a first interlayer insulating layer surrounding (i.e., extending around) a sidewall of each of the first to third wiring patterns on the upper surface of the substrate, the first interlayer insulating layer including a first material having a first dielectric constant, a second interlayer insulating layer being in contact with an upper surface of the first interlayer insulating layer, at least a portion of the second interlayer insulating layer overlapping each of the first to third wiring patterns in the horizontal direction, the second interlayer insulating layer including a second material having a second dielectric constant greater than the first dielectric constant, the second interlayer insulating layer including a first portion between the first wiring pattern and the second wiring pattern, and a second portion between the second wiring pattern and the third wiring pattern, a third interlayer insulating layer on an upper surface of the second interlayer insulating layer, the third interlayer insulating layer including a third material having a third dielectric constant lower than the second dielectric constant, and an etching stop layer between the third interlayer insulating layer and each of an upper surface of the second wiring pattern, an upper surface of the third wiring pattern and the upper surface of the second interlayer insulating layer, wherein a pitch between the second wiring pattern and the third wiring pattern in the horizontal direction is greater than a pitch between the first wiring pattern and the second wiring pattern in the horizontal direction, and wherein a vertical level of a lowermost surface of the second portion of the second interlayer insulating layer is lower than a vertical level of a lowermost surface of the first portion of the second interlayer insulating layer relative to the upper surface of the substrate as a reference layer.

According to some embodiments of the present disclosure, there is provided a semiconductor device, comprising a substrate, first to third wiring patterns sequentially spaced apart from each other in a horizontal direction on an upper surface of the substrate, a first interlayer insulating layer surrounding a sidewall of each of the first to third wiring patterns on the upper surface of the substrate, the first interlayer insulating layer including a first material having a first dielectric constant, a second interlayer insulating layer being in contact with an upper surface of the first interlayer insulating layer, at least a portion of the second interlayer insulating layer overlapping each of the first to third wiring patterns in the horizontal direction, a vertical level of an upper surface of the second interlayer insulating layer being higher than a vertical level of an upper surface of each of the first to third wiring patterns relative to the upper surface of the substrate, the second interlayer insulating layer being in contact with a sidewall of each of the first to third wiring patterns, the second interlayer insulating layer including a second material having a second dielectric constant greater than the first dielectric constant, the second interlayer insulating layer including a first portion disposed between the first wiring pattern and the second wiring pattern, and a second portion between the second wiring pattern and the third wiring pattern, a third interlayer insulating layer on the upper surface of the second interlayer insulating layer, the third interlayer insulating layer including a third material having a third dielectric constant lower than the second dielectric constant, an etching stop layer between the third interlayer insulating layer and each of the upper surface of the second wiring pattern, the upper surface of the third wiring pattern and the upper surface of the second interlayer insulating layer, and a via penetrating the third interlayer insulating layer and the etching stop layer in a vertical direction, the via connected to the first wiring pattern, at least a portion of the via being in contact with the upper surface of the second interlayer insulating layer, wherein each of the first and second interlayer insulating layers are non-overlapping relative to each of the first to third wiring patterns in the vertical direction, wherein a pitch between the second wiring pattern and the third wiring pattern in the horizontal direction is greater than a pitch between the first wiring pattern and the second wiring pattern in the horizontal direction, and wherein a vertical level of a lowermost surface of the second portion of the second interlayer insulating layer is lower than a vertical level of a lowermost surface of the first portion of the second interlayer insulating layer.

Purposes according to the present disclosure are not limited to the above-mentioned purpose. Other purposes and advantages according to the present disclosure that are not mentioned may be understood based on the following descriptions, and may be more clearly understood based on embodiments according to the present disclosure. Further, it will be easily understood that the purposes and advantages according to the present disclosure may be realized using means illustrated in the claims and combinations thereof.

### BRIEF DESCRIPTION OF DRAWINGS

The above and other aspects and features of the present disclosure will become more apparent by describing in detail embodiments thereof with reference to the attached drawings, wherein like reference numerals (when used) indicate corresponding elements throughout the several views, and in which:

FIG. 1 is a schematic cross-sectional view illustrating a semiconductor device according to some embodiments of the present disclosure.

FIGS. 2 to 9 are schematic cross-sectional views depicting intermediate structures corresponding to intermediate steps of an example method for manufacturing a semiconductor device according to some embodiments of the present disclosure;

FIG. 10 is a schematic cross-sectional view illustrating an example semiconductor device according to one or more embodiments of the present disclosure;

FIGS. 11 to 13 are schematic cross-sectional views depicting intermediate structures corresponding to intermediate steps of an example method for manufacturing a semiconductor device according to one or more embodiments of the present disclosure;

FIG. 14 is a schematic cross-sectional view illustrating a semiconductor device according to one or more embodiments of the present disclosure.

FIGS. 15 to 20 are schematic cross-sectional views depicting intermediate structures corresponding to intermediate steps of an example method for manufacturing a semiconductor device according to still further embodiments of the present disclosure;

FIG. 21 is a schematic cross-sectional view illustrating a semiconductor device according to still further embodiments of the present disclosure; and

FIGS. 22 to 24 are schematic cross-sectional views depicting intermediate structures corresponding to intermediate steps of an example method for manufacturing a semiconductor device according to still further embodiments of the present disclosure.

### DETAILED DESCRIPTION

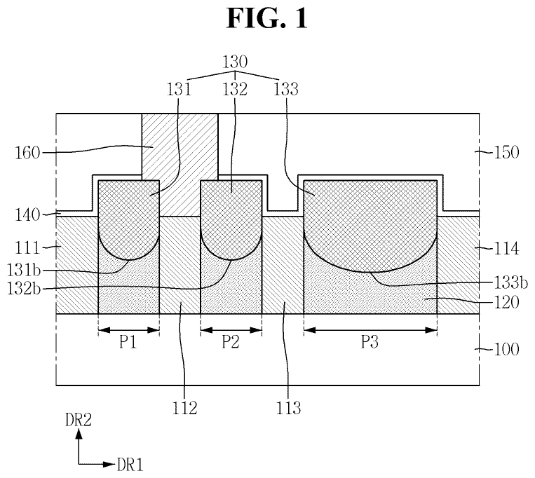

Hereinafter, a semiconductor device according to some embodiments of the present disclosure is described with reference to FIG. 1.

FIG. 1 is a schematic cross-sectional view illustrating a semiconductor device according to some embodiments of the present disclosure.

Referring to FIG. 1, the semiconductor device according to some embodiments of the present disclosure includes a substrate 100, first to fourth wiring patterns 111, 112, 113, and 114, a first interlayer insulating layer 120, a second interlayer insulating layer 130, an etching stop layer 140, a third interlayer insulating layer 150, and a via 160.

The substrate 100 may have a stack structure in which a base substrate and an epitaxial layer are formed thereon. However, the present disclosure is not limited thereto. The substrate 100 may be embodied as a silicon substrate, a gallium arsenide substrate, a silicon germanium substrate, a ceramic substrate, a quartz substrate, or a glass substrate for a display, or may be a SOI (semiconductor-on-insulator) substrate.

Furthermore, although not shown, the substrate 100 may include a conductive pattern. The conductive pattern may be a metal wiring or a contact, may be or a gate electrode of a transistor, a source/drain of a transistor, or a diode, etc. However, the present disclosure is not limited thereto.

Hereinafter, a horizontal direction DR1 may be defined as a direction parallel to an upper surface of the substrate 100. A vertical direction DR2 may be defined as a direction perpendicular to the horizontal direction DR1. That is, the vertical direction DR2 may be defined as a direction perpendicular to the upper surface of the substrate 100.

Each of the first to fourth wiring patterns 111, 112, 113, and 114 may be disposed on the upper surface of the substrate 100. The first to fourth wiring patterns 111, 112, 113, and 114 may be sequentially spaced apart from each other in the horizontal direction DR1. For example, the second wiring pattern 112 may be spaced apart from the first wiring pattern 111 in the horizontal direction DR1. The third wiring pattern 113 may be spaced apart from the second wiring pattern 112 in the horizontal direction DR1. The fourth wiring pattern 114 may be spaced apart from the third wiring pattern 113 in the horizontal direction DR1. For example, a lower surface of each of the first to fourth wiring patterns 111, 112, 113, and 114 may contact the upper surface of the substrate 100. For example, upper surfaces of the first to fourth wiring patterns 111, 112, 113, and 114 may be coplanar with each other. The term “contact” (or “contacting,” or like terms, such as “connect” or “connecting”), as may be used herein, is intended to refer to a physical and/or electrical connection between two or more elements, and may include other intervening elements. As used herein, the term “and/or” includes any and all combinations of one or more of the associated listed items.

In FIG. 1, widths of the first to fourth wiring patterns 111, 112, 113, and 114 in the horizontal direction DR1 are shown to be equal to each other. However, this is for convenience of illustration, and the widths of the first to fourth wiring patterns 111, 112, 113, and 114 in the horizontal direction DR1 may be different from each other. For example, a pitch P1 in the horizontal direction DR1 between the first wiring pattern 111 and the second wiring pattern 112 may be equal to a pitch P2 in the horizontal direction DR1 between the second wiring pattern 112 and the third wiring pattern 113. For example, a pitch P3 in the horizontal direction DR1 between the third wiring pattern 113 and the fourth wiring pattern 114 may be larger than each of the pitch P1 in the horizontal direction DR1 between the first wiring pattern 111 and the second wiring pattern 112, and the pitch P2 in the horizontal direction DR1 between the second wiring pattern 112 and the third wiring pattern 113.

Each of the first to fourth wiring patterns 111, 112, 113, and 114 may include a conductive material. For example, each of the first to fourth wiring patterns 111, 112, 113, and 114 may include one of titanium (Ti), titanium nitride (TiN), tantalum (Ta), tantalum nitride (TaN), tantalum carbonitride (TaCN), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), copper (Cu), carbon (C), silver (Ag), cobalt (Co), indium (In), tin (Sn), zinc (Zn), manganese (Mn), magnesium (Mg), chromium (Cr), germanium (Ge), strontium (Sr), platinum (Pt), aluminum (Al), ruthenium (Ru), iridium (Ir), rhodium (Rh), and combinations thereof. However, the present disclosure is not limited thereto.

The first interlayer insulating layer 120 may surround a sidewall of each of the first to fourth wiring patterns 111, 112, 113, and 114 while being disposed on the upper surface of the substrate 100. For example, the first interlayer insulating layer 120 may contact the upper surface of the substrate 100. For example, the first interlayer insulating layer 120 may contact the sidewall of each of the first to fourth wiring patterns 111, 112, 113, and 114. For example, a vertical level of an upper surface of the first interlayer insulating layer 120 may be lower than a vertical level of an upper surface of each of the first to fourth wiring patterns 111, 112, 113, and 114. For example, the first interlayer insulating layer 120 does not overlap each of the first to fourth wiring patterns 111, 112, 113, and 114 in the vertical direction DR2. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The term “overlap” (or “overlapping,” or like terms), as may be used herein, is intended to broadly refer to a first element that intersects with at least a portion of a second element in the vertical direction (i.e., direction DR2), but does not require that the first and second elements be completely aligned with one another in a horizontal plane (i.e., direction DR1).

The first interlayer insulating layer 120 may include a low dielectric constant material. For example, the first interlayer insulating layer 120 may include a first material having a first dielectric constant. For example, the first dielectric constant may range from 1.8 to 3.1. For example, the first material included in the first interlayer insulating layer 120 may include silicon oxycarbide (SiOC), silicon oxycarbonitride (SiOCN), or silicon acid fluoride (SiOF). However, the present disclosure is not limited thereto. In some alternative embodiments, the first material included in the first interlayer insulating layer 120 may include another insulating material having a dielectric constant in a range of 1.8 to 3.1.

The second interlayer insulating layer 130 may be disposed on the upper surface of the first interlayer insulating layer 120. For example, the second interlayer insulating layer 130 may surround a portion of the side wall of each of the first to fourth wiring patterns 111, 112, 113, and 114. For example, a lower surface of the second interlayer insulating layer 130 may contact an upper surface of the first interlayer insulating layer 120. For example, the second interlayer insulating layer 130 may contact the sidewall of each of the first to fourth wiring patterns 111, 112, 113, and 114.

For example, a vertical level of an upper surface of the second interlayer insulating layer 130 may be higher than that of the upper surface of each of the first to fourth wiring patterns 111, 112, 113, and 114 relative to the upper surface of the substrate 100 as a reference layer. For example, the second interlayer insulating layer 130 is not disposed on the upper surface of each of the first to fourth wiring patterns 111, 112, 113, and 114. That is, the second interlayer insulating layer 130 does not overlap each of the first to fourth wiring patterns 111, 112, 113, and 114 in the vertical direction DR2.

For example, the second interlayer insulating layer 130 may include first to third portions 131, 132, and 133. At least a portion of the first portion 131 of the second interlayer insulating layer 130 may be disposed between the first wiring pattern 111 and the second wiring pattern 112. At least a portion of the second portion 132 of the second interlayer insulating layer 130 may be disposed between the second wiring pattern 112 and the third wiring pattern 113. At least a portion of the third portion 133 of the second interlayer insulating layer 130 may be disposed between the third wiring pattern 113 and the fourth wiring pattern 114.

For example, at least a portion of the first portion 131 of the second interlayer insulating layer 130 may overlap each of the first wiring pattern 111 and the second wiring pattern 112 in the horizontal direction DR1. At least a portion of the second portion 132 of the second interlayer insulating layer 130 may overlap each of the second wiring pattern 112 and the third wiring pattern 113 in the horizontal direction DR1. At least a portion of the third portion 133 of the second interlayer insulating layer 130 may overlap each of the third wiring pattern 113 and the fourth wiring pattern 114 in the horizontal direction DR1.

For example, a width in the horizontal direction DR1 of the third portion 133 of the second interlayer insulating layer 130 may be larger than each of a width in the horizontal direction DR1 of the first portion 131 of the second interlayer insulating layer 130 and a width and a width in the horizontal direction DR1 of the second portion 132 of the second interlayer insulating layer 130. For example, the width in the horizontal direction DR1 of the second portion 132 of the second interlayer insulating layer 130 may be equal to the width in the horizontal direction DR1 of the first portion 131 of the second interlayer insulating layer 130. However, the present disclosure is not limited thereto. For example, the second interlayer insulating layer 130 may be formed so that upper surfaces of the first to third portions 131, 132, and 133 are coplanar with each other, relative to the upper surface of the substrate 100. For example, a vertical level of the upper surface of each of the first to third portions 131, 132, and 133 of the second interlayer insulating layer 130 may be higher than that of the upper surface of each of the first to fourth wiring patterns 111, 112, 113, and 114 relative to the upper surface of the substrate 100.

For example, the first portion 131 of the second interlayer insulating layer 130 does not overlap each of the first wiring pattern 111 and the second wiring pattern 112 in the vertical direction DR2. The second portion 132 of the second interlayer insulating layer 130 does not overlap each of the second wiring pattern 112 and the third wiring pattern 113 in the vertical direction DR2. The third portion 133 of the second interlayer insulating layer 130 does not overlap each of the third wiring pattern 113 and the fourth wiring pattern 114 in the vertical direction DR2.

For example, at least a portion of a sidewall of the first portion 131 of the second interlayer insulating layer 130 may contact each of a sidewall of the first wiring pattern 111 and a sidewall of the second wiring pattern 112. At least a portion of a sidewall of the second portion 132 of the second interlayer insulating layer 130 may be in contact with a sidewall of each of the second wiring pattern 112 and the third wiring pattern 113. At least a portion of a sidewall of the third portion 133 of the second interlayer insulating layer 130 may be in contact with a sidewall of each of the third wiring pattern 113 and the fourth wiring pattern 114.

For example, a lower surface of each of the first to third portions 131, 132, and 133 of the second interlayer insulating layer 130 may be formed to be convex toward the upper surface of the substrate 100. For example, a vertical level of the lowermost surface 133b of the third portion 133 of the second interlayer insulating layer 130 may be lower than that of each of the lowermost surface 131b of the first portion 131 of the second interlayer insulating layer 130 and the lowermost surface 132b of the second portion 132 of the second interlayer insulating layer 130. For example, the lowermost surface 132b of the second portion 132 of the second interlayer insulating layer 130 is coplanar with the lowermost surface 131b of the first portion 131 of the second interlayer insulating layer 130. However, the present disclosure is not limited thereto.

For example, a density of the second interlayer insulating layer 130 may be greater than a density of the first interlayer insulating layer 120. The second interlayer insulating layer 130 may include a low dielectric constant material. For example, the second interlayer insulating layer 130 may include a second material having a second dielectric constant greater than the first dielectric constant. For example, the second dielectric constant may range from 3.1 to 8. For example, the second material included in the second interlayer insulating layer 130 may include silicon oxycarbide (SiOC), silicon oxide (SiO₂), or silicon aluminum oxide (SiAlO).

For example, the second material included in the second interlayer insulating layer 130 may be different from the first material included in the first interlayer insulating layer 120. In some alternative embodiments, the second material included in the second interlayer insulating layer 130 may be identical with the first material included in the first interlayer insulating layer 120. For example, the first material included in the first interlayer insulating layer 120 and the second material included in the second interlayer insulating layer 130 may include silicon oxycarbide (SiOC). When each of the first material and the second material includes silicon oxycarbide (SiOC), a concentration of carbon (C) contained in the second material may be lower than a concentration of carbon (C) contained in the first material. In this regard, the concentration of carbon (C) refers to an atomic ratio of carbon (C) atoms to silicon oxycarbide (SiOC).

The third interlayer insulating layer 150 may be disposed on an upper surface of each of the first wiring pattern 111, the third wiring pattern 113, the fourth wiring pattern 114, and the second interlayer insulating layer 130. Although not shown in FIG. 1, the third interlayer insulating layer 150 may also be disposed on the upper surface of the second wiring pattern 112 in a region where the via 160 is not disposed. For example, at least a portion of the third interlayer insulating layer 150 may be disposed between the second portion 132 of the second interlayer insulating layer 130 and the third portion 133 of the second interlayer insulating layer 130 while being disposed on the upper surface of the third wiring pattern 113.

For example, a density of the third interlayer insulating layer 150 may be lower than a density of the second interlayer insulating layer 130. However, the present disclosure is not limited thereto. The third interlayer insulating layer 150 may include a low dielectric constant material. For example, the third interlayer insulating layer 150 may include a third material having a third dielectric constant lower than the second dielectric constant. For example, the third dielectric constant may range from 1.8 to 3.1. For example, the third material included in the third interlayer insulating layer 150 may include silicon oxycarbide (SiOC), silicon oxycarbonitride (SiOCN), or silicon acid fluoride (SiOF). However, the present disclosure is not limited thereto. In some alternative embodiments, the third material included in the third interlayer insulating layer 150 may include another insulating material having a dielectric constant in a range of 1.8 to 3.1.

The etching stop layer 140 may be disposed between each of the first wiring pattern 111, the third wiring pattern 113, the fourth wiring pattern 114, and the second interlayer insulating layer 130 and the third interlayer insulating layer 150. For example, the etching stop layer 140 is not disposed between each of the first portion 131 of the second interlayer insulating layer 130, the second portion 132 of the second interlayer insulating layer 130, and the second wiring pattern 112 and the via 160. For example, the etching stop layer 140 may be in contact with each of the first wiring pattern 111, the third wiring pattern 113, the fourth wiring pattern 114, the second interlayer insulating layer 130, and the third interlayer insulating layer 150. For example, the etching stop layer 140 may be formed conformally. The term “conformally” (or “conformal,” or like terms), as may be used herein in the context of a material layer or coating, is intended to refer broadly to a material layer or coating having a substantially uniform cross-sectional thickness relative to the contour of a surface to which the material layer is applied.

In FIG. 1, the etching stop layer 140 is shown as being formed as a single film. However, the present disclosure is not limited thereto. In some alternative embodiments, the etching stop layer 140 may be formed as a stack of multiple films. For example, the etching stop layer 140 may include at least one of aluminum nitride (AlN), aluminum oxide (AlO), hafnium oxide (HfO), zirconium oxide (ZrO), hafnium nitride (HfN), zirconium nitride (ZrN), silicon oxide (SiO₂), silicon nitride (SiN), silicon oxynitride (SiCN), silicon oxycarbide (SiOC), silicon carbide (SiC), and a low dielectric constant material.

The via 160 may penetrate (i.e., extend in) the third interlayer insulating layer 150 and the etching stop layer 140 in the vertical direction DR2 so as to contact the second wiring pattern 112. For example, at least a portion of the via 160 may be disposed between the first portion 131 of the second interlayer insulating layer 130 and the second portion 132 of the second interlayer insulating layer 130. For example, the via 160 may contact each of a sidewall of the first portion 131 of the second interlayer insulating layer 130 and a sidewall of the second portion 132 of the second interlayer insulating layer 130. For example, at least a portion of the via 160 may contact each of the upper surface of the first portion 131 of the second interlayer insulating layer 130 and the upper surface of the second portion 132 of the second interlayer insulating layer 130.

In FIG. 1, the via 160 is shown as being disposed on the upper surface of the second wiring pattern 112. However, the present disclosure is not limited thereto. In some alternative embodiments, the via 160 may be disposed on the upper surface of the third wiring pattern 113. That is, in some alternative embodiments, the via 160 may penetrate the third interlayer insulating layer 150 and the etching stop layer 140 in the vertical direction DR2 so as to contact the third wiring pattern 113. The via 160 may include a conductive material. In FIG. 1, via 160 is shown as being formed as a single film. However, the present disclosure is not limited thereto. In some alternative embodiments, the via 160 may be formed as a stack of multiple films.

Hereinafter, a method for manufacturing a semiconductor device according to some embodiments of the present disclosure will be described with reference to FIGS. 1 to 9.

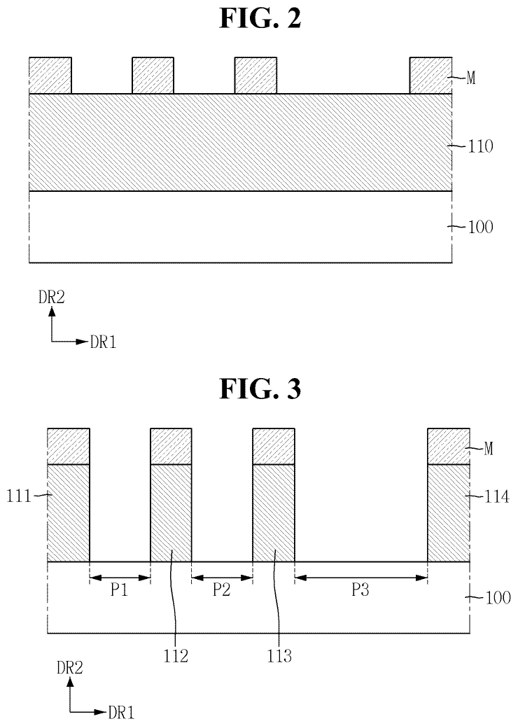

FIGS. 2 to 9 are schematic cross-sectional views depicting intermediate structures corresponding to intermediate steps of an example method for manufacturing a semiconductor device according to some embodiments of the present disclosure.

Referring to FIG. 2, a wiring material layer 110 may be formed on the upper surface of the substrate 100. The wiring material layer 110 may include a conductive material. For example, the upper surface of the wiring material layer 110 may be formed to be flat (i.e., horizontally planar). However, the present disclosure is not limited thereto. Subsequently, a mask pattern M may be formed on the upper surface of the wiring material layer 110. For example, the mask pattern M may include a different material from that of the second interlayer insulating layer (130 in FIG. 1). For example, the mask pattern M may include silicon nitride (SiN), silicon oxynitride (SiON), or silicon carbonitride (SiCN). However, the present disclosure is not limited thereto.

Referring to FIG. 3, using the mask pattern M as an etch mask, the wiring material layer (110 in FIG. 2) may be etched to form the first to fourth wiring patterns 111, 112, 113, and 114. For example, the first to fourth wiring patterns 111, 112, 113, and 114 may be sequentially spaced apart from each other in the horizontal direction DR1. For example, the pitch P1 in the horizontal direction DR1 between the first wiring pattern 111 and the second wiring pattern 112 may be equal to the pitch P2 in the horizontal direction DR1 between the second wiring pattern 112 and the third wiring pattern 113. For example, the pitch P3 in the horizontal direction DR1 between the third wiring pattern 113 and the fourth wiring pattern 114 may be larger than each of the pitch P1 in the horizontal direction DR1 between the first wiring pattern 111 and the second wiring pattern 112 and the pitch P2 in the horizontal direction DR1 between the second wiring pattern 112 and the third wiring pattern 113.

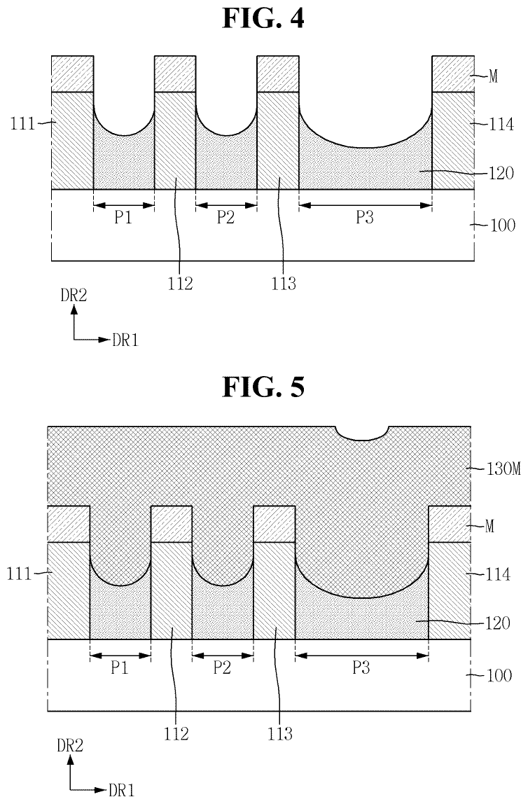

Referring to FIG. 4, the first interlayer insulating layer 120 may be formed on the upper surface of the substrate 100. For example, the first interlayer insulating layer 120 may surround a portion of the side wall of each of the first to fourth wiring patterns 111, 112, 113, and 114. For example, the upper surface of the first interlayer insulating layer 120 may be concavely formed toward the upper surface of the substrate 100. For example, the upper surface of the first interlayer insulating layer 120 may be formed at a lower vertical level than that of the upper surface of each of the first to fourth wiring patterns 111, 112, 113, and 114. The first interlayer insulating layer 120 may include a low dielectric constant material. For example, the first interlayer insulating layer 120 may include the first material having the first dielectric constant.

Referring to FIG. 5, an insulating material layer 130M may be formed on the upper surface of the first interlayer insulating layer 120. For example, the insulating material layer 130M may cover a sidewall and an upper surface of the mask pattern M, and an exposed portion of the sidewall of each of the first to fourth wiring patterns 111, 112, 113, and 114. For example, the insulating material layer 130M may include a low dielectric constant material. For example, the insulating material layer 130M may include the second material having the second dielectric constant greater than the first dielectric constant. For example, a density of the insulating material layer 130M may be greater than the density of the first interlayer insulating layer 120. The term “cover” (or “covering,” “covers,” or like terms), as may be used herein, is intended to broadly refer to an element, structure or layer that is on or over another element, structure or layer, either directly or with one or more other intervening elements, structures or layers therebetween. The term “exposed” (or “exposes,” or like terms) may be used herein to describe relationships between elements and/or with reference to intermediate processes in fabricating an integrated circuit device, but may not require exposure of a particular element in the completed device. Likewise, the term “not exposed” may be used to described relationships between elements and/or with reference to intermediate processes in fabricating an integrated circuit device, but may not require a particular element to be unexposed in the completed device.

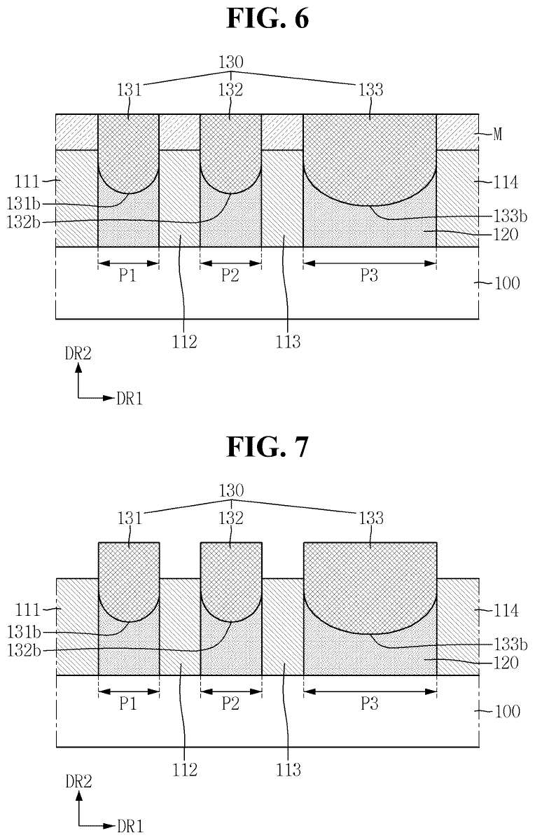

Referring to FIG. 6, a portion of the insulating material layer (130M in FIG. 5) may be etched by performing a planarization process (e.g., a CMP process). Through the planarization process, the upper surface of the mask pattern M may be exposed. After the planarization process is performed, the remaining insulating material layer (130M in FIG. 5) may be defined as the second interlayer insulating layer 130M.

For example, a portion of the insulating material layer (130M in FIG. 5) remaining between the first wiring pattern 111 and the second wiring pattern 112 may be defined as the first portion 131 of the second interlayer insulating layer 130. A portion of the insulating material layer (130M in FIG. 5) remaining between the second wiring pattern 112 and the third wiring pattern 113 may be defined as the second portion 132 of the second interlayer insulating layer 130. The insulating material layer (130M in FIG. 5) remaining between the third wiring pattern 113 and the fourth wiring pattern 114 may be defined as the third portion 133 of the second interlayer insulating layer 130. For example, the upper surface of the mask pattern M may be coplanar with the upper surface of each of the first to third portions 131, 132, and 133 of the second interlayer insulating layer 130.

Referring to FIG. 7, the mask pattern (M in FIG. 6) may be removed. Thus, on the upper surface of each of the first to fourth wiring patterns 111, 112, 113, and 114, a portion of the side wall of each of the first to third portions 131, 132 and 133 of the second interlayer insulating layer 130 may be exposed.

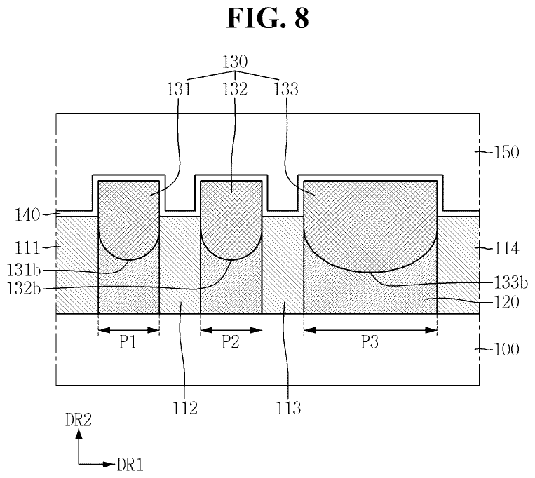

Referring to FIG. 8, an etching stop layer 140 may be formed on the upper surface of each of the first to fourth wiring patterns 111, 112, 113, and 114 and an exposed portion of each of the side wall and the upper surface of each of the first to third portions 131, 132, and 133 of the second interlayer insulating layer 130. For example, the etching stop layer 140 may be formed conformally.

Subsequently, the third interlayer insulating layer 150 may be formed on the upper surface of the etching stop layer 140. For example, the third interlayer insulating layer 150 may include a low dielectric constant material. For example, the third interlayer insulating layer 150 may include the third material having the third dielectric constant lower than the second dielectric constant. For example, the density of the third interlayer insulating layer 150 may be lower than the density of the second interlayer insulating layer 130.

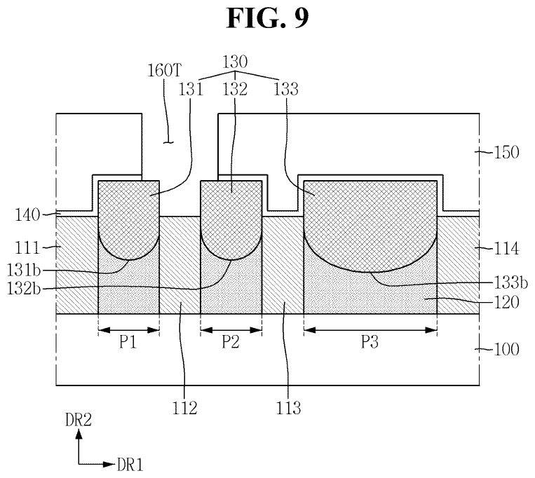

Referring to FIG. 9, a via trench 160T penetrating the third interlayer insulating layer 150 and the etching stop layer 140 in the vertical direction DR2 may be formed on the upper surface of the second wiring pattern 112. For example, each of the upper surface of the second wiring pattern 112, the sidewall of the first portion 131 of the second interlayer insulating layer 130, and the side wall of the second portion 132 the second interlayer insulating layer 130 may be exposed through the via trench 160T. Furthermore, each of a portion of the upper surface of the first portion 131 of the second interlayer insulating layer 130 and a portion of the upper surface of the second portion 132 of the second interlayer insulating layer 130 may be exposed through the via trench 160T.

Referring to FIG. 1, the via 160 may be formed inside the via trench (160T in FIG. 9). The via 160 may contact the upper surface of the second wiring pattern 112. Furthermore, the via 160 may contact each of the sidewall of the first portion 131 of the second interlayer insulating layer 130 and the sidewall of the second portion 132 of the second interlayer insulating layer 130. Furthermore, the via 160 may contact the portion of the upper surface of the first portion 131 of the second interlayer insulating layer 130 and the portion of the upper surface of the second portion 132 of the second interlayer insulating layer 130. Through this manufacturing process, the semiconductor device as shown in FIG. 1 may be manufactured.

In the method for manufacturing a semiconductor device according to some embodiments of the present disclosure, between the adjacent ones of the plurality of wiring patterns 111, 112, 113, and 114, the second interlayer insulating layer 130 including the second material having the second dielectric constant greater than the first dielectric constant may be formed on the upper surface of the first interlayer insulating layer 120 including the first material having the first dielectric constant. Furthermore, the density of the second interlayer insulating layer 130 may be greater than the density of the first interlayer insulating layer 120. In the method for manufacturing the semiconductor device according to some embodiments of the present disclosure, the first interlayer insulating layer 120 may be prevented from being damaged using the second interlayer insulating layer 130 having the higher dielectric constant and density, in the subsequent process such as the planarization process (e.g., CMP process) and the etching process.

The semiconductor device according to some embodiments of the present disclosure manufactured by the above manufacturing method may include the first interlayer insulating layer 120 and the second interlayer insulating layer 130 between adjacent ones of the plurality of wiring patterns 111, 112, 113, and 114. The second interlayer insulating layer 130 may be disposed on the upper surface of the first interlayer insulating layer 120, and each of the first interlayer insulating layer 120 and the second interlayer insulating layer 130 may include a low dielectric constant material. The second dielectric constant of the second material included in the second interlayer insulating layer 130 may be greater than the first dielectric constant of the first material included in the first interlayer insulating layer 120. Furthermore, the density of the second interlayer insulating layer 130 may be greater than the density of the first interlayer insulating layer 120.

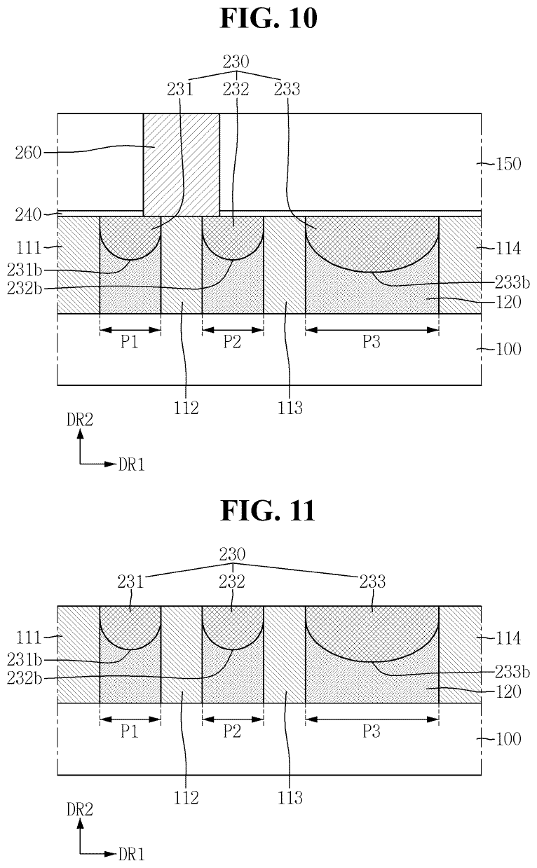

Hereinafter, with reference to FIG. 10, a semiconductor device according to one or more embodiments of the present disclosure is described. The following description focuses on differences thereof from the semiconductor device as shown in FIG. 1.

FIG. 10 is a schematic cross-sectional view illustrating a semiconductor device according to one or more embodiments of the present disclosure.

Referring to FIG. 10, in the semiconductor device according to some embodiments of the present disclosure, the upper surface of a second interlayer insulating layer 230 may be coplanar with the upper surface of each of the first to fourth wiring patterns 111, 112, 113, and 114 in the horizontal direction DR1, relative to the upper surface of the substrate as a reference layer.

For example, the second interlayer insulating layer 230 may include first to third portions 231, 232, and 233. The first portion 231 of the second interlayer insulating layer 230 may be disposed between the first wiring pattern 111 and the second wiring pattern 112. The second portion 232 of the second interlayer insulating layer 230 may be disposed between the second wiring pattern 112 and the third wiring pattern 113. The third portion 233 of the second interlayer insulating layer 230 may be disposed between the third wiring pattern 113 and the fourth wiring pattern 114. For example, the upper surface of each of the first to third portions 231, 232, and 233 of the second interlayer insulating layer 230 may be coplanar with the upper surface of each of the first to fourth wiring patterns 111, 112, 113, and 114 relative to the upper surface of the substrate 100.

For example, an etching stop layer 240 may be in contact with the upper surface of each of the first wiring pattern 111, the third wiring pattern 113, the fourth wiring pattern 114, and the second interlayer insulating layer 230. For example, the etching stop layer 240 does not contact a sidewall of the second interlayer insulating layer 230. For example, a via 260 may penetrate (i.e., extend in) the third interlayer insulating layer 150 and the etching stop layer 240 in the vertical direction DR2 so as to contact the second wiring pattern 112.

For example, the lower surface of the via 260 is in contact with the upper surface of the second wiring pattern 112, at least a portion of the upper surface of the first portion 231 of the second interlayer insulating layer 230, and at least a portion of the second portion 232 of the second interlayer insulating layer 230. For example, the via 260 does not contact each of a sidewall of the first portion 231 of the second interlayer insulating layer 230 and a sidewall of the second portion 232 of the second interlayer insulating layer 230.

For example, a lowermost surface 233b of the third portion 233 of the second interlayer insulating layer 230 may be formed at a lower level than that of each of the lowermost surface 231b of the first portion 231 of the second interlayer insulating layer 230 and the lowermost surface 232b of the second portion 232 of the second interlayer insulating layer 230, relative to the upper surface of the substrate 100. For example, the lowermost surface 232b of the second portion 232 of the second interlayer insulating layer 230 may have the same vertical level as that of the lowermost surface 231b of the first portion 231 of the second interlayer insulating layer 230. However, the present disclosure is not limited thereto.

Hereinafter, a method for manufacturing a semiconductor device according to further some embodiments of the present disclosure is described with reference to FIGS. 10 to 13. The following description focuses on differences thereof from the method for manufacturing the semiconductor device as shown in FIGS. 2 to 9.

FIGS. 11 to 13 are schematic cross-sectional views of intermediate structures corresponding to intermediate steps of an example method for manufacturing a semiconductor device according to one or more embodiments of the present disclosure.

Referring to FIG. 11, after the manufacturing process as shown in FIGS. 2 to 5 has been performed, a planarization process (e.g., CMP process) may be performed to remove a portion of the insulating material layer (130M in FIG. 5) and the mask pattern (M in FIG. 5). Through the planarization process, the upper surface of each of the first to fourth wiring patterns 111, 112, 113, and 114 may be exposed. After the planarization process has been performed, the remaining insulating material layer (130M in FIG. 5) may be defined as the second interlayer insulating layer 230.

For example, a portion of the insulating material layer (130M in FIG. 5) remaining between the first wiring pattern 111 and the second wiring pattern 112 may be defined as the first portion 231 of the second interlayer insulating layer 230. A portion of the insulating material layer (130M in FIG. 5) remaining between the second wiring pattern 112 and the third wiring pattern 113 may be defined as the second portion 232 of the second interlayer insulating layer 230. A portion of the insulating material layer (130M in FIG. 5) remaining between the third wiring pattern 113 and the fourth wiring pattern 114 may be defined as the third portion 233 of the second interlayer insulating layer 230. For example, the upper surface of each of the first to fourth wiring patterns 111, 112, 113, and 114 may be horizontally coplanar with the upper surface of each of the first to third portions 131, 132 and 133 of the second interlayer insulating layer 130, relative to the upper surface of the substrate 100.

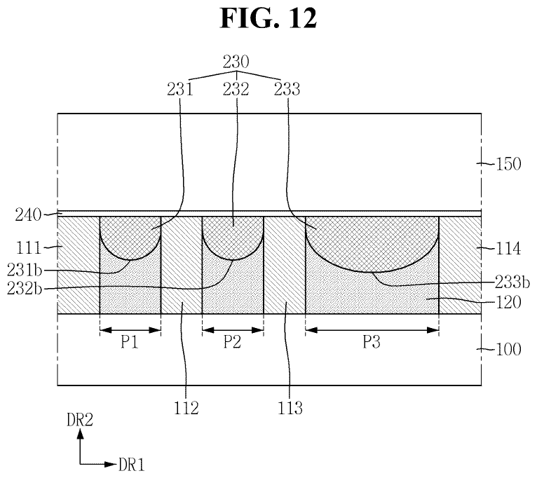

Referring to FIG. 12, the etching stop layer 240 and the third interlayer insulating layer 150 may be sequentially formed on the upper surface of each of the first to fourth wiring patterns 111, 112, 113, and 114 and the upper surface of each of the first to third portions 231, 232 and 233 of the second interlayer insulating layer 230.

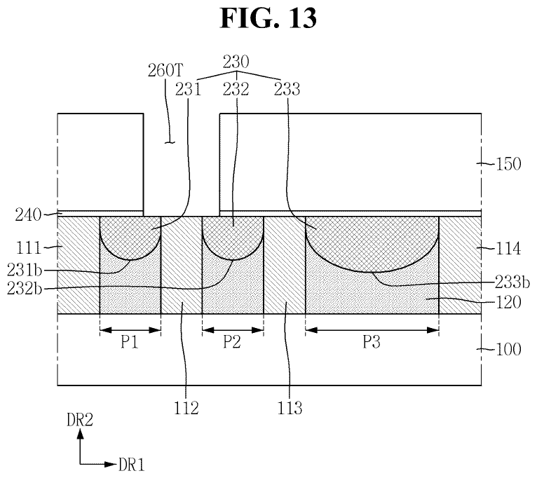

Referring to FIG. 13, the via trench 260T penetrating the third interlayer insulating layer 150 and the etching stop layer 240 in the vertical direction DR2 may be formed on the upper surface of the second wiring pattern 112. For example, each of the upper surface of the second wiring pattern 112, a portion of the upper surface of the first portion 231 of the second interlayer insulating layer 230, and a portion of the upper surface of the second portion 232 of the second interlayer insulating layer 230 may be exposed through the via trench 260T.

Referring to FIG. 10, the via 260 may be formed inside the via trench (260T in FIG. 13). The via 260 may contact the upper surface of the second wiring pattern 112. Furthermore, the via 260 may contact each of a portion of the upper surface of the first portion 231 of the second interlayer insulating layer 230 and a portion of the upper surface of the second portion 232 of the second interlayer insulating layer 230, respectively. Through this manufacturing process, the semiconductor device as shown in FIG. 10 may be manufactured.

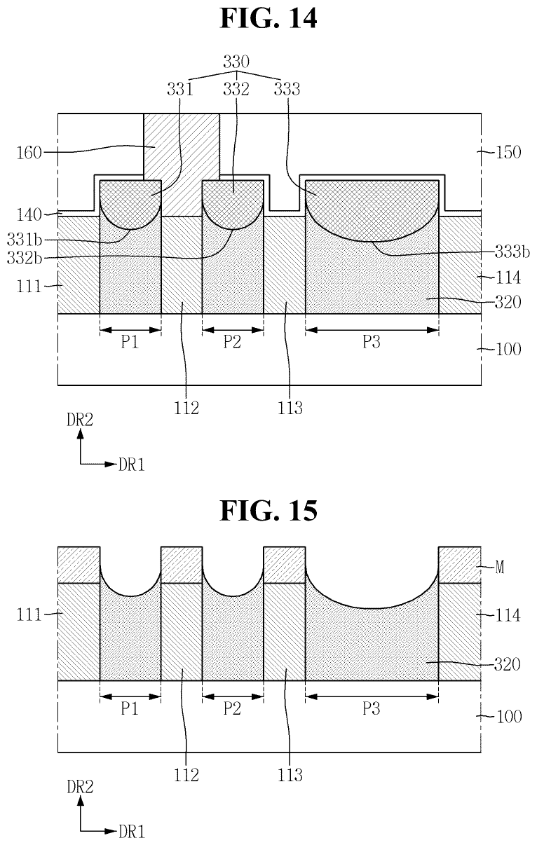

Hereinafter, with reference to FIG. 14, a semiconductor device according to one or more embodiments of the present disclosure will be described. The following description focuses on differences thereof from the semiconductor device as shown in FIG. 1.

FIG. 14 is a schematic cross-sectional view illustrating a semiconductor device according to one or more embodiments of the present disclosure.

Referring to FIG. 14, in a semiconductor device according to one or more embodiments of the present disclosure, a second interlayer insulating layer 330 may be spaced apart from, in the horizontal direction DR1, the sidewall of each of the first to fourth wiring patterns 111, 112, 113, and 114. That is, the second interlayer insulating layer 330 does not contact the sidewall of each of the first to fourth wiring patterns 111, 112, 113, and 114.

For example, the second interlayer insulating layer 330 may include first to third portions 331, 332, and 333. At least a portion of the first portion 331 of the second interlayer insulating layer 330 may be disposed between the first wiring pattern 111 and the second wiring pattern 112. At least a portion of the second portion 332 of the second interlayer insulating layer 330 may be disposed between the second wiring pattern 112 and the third wiring pattern 113. At least a portion of the third portion 333 of the second interlayer insulating layer 330 may be disposed between the third wiring pattern 113 and the fourth wiring pattern 114. For example, a vertical level of the upper surface of each of the first to third portions 331, 332, and 333 of the second interlayer insulating layer 330 may be higher than a vertical level of the upper surface of each of the first to fourth wiring patterns 111, 112, 113, and 114.

For example, a vertical level of the uppermost surface of the first interlayer insulating layer 320 may be higher than that of the upper surface of each of the first to fourth wiring patterns 111, 112, 113, and 114. The vertical level of the uppermost surface of a first interlayer insulating layer 320 may be higher than that of the lower surface of the via 160, relative to the upper surface of the substrate 100. For example, at least a portion of the first interlayer insulating layer 320 may be disposed between each of the first to fourth wiring patterns 111, 112, 113, and 114 and the second interlayer insulating layer 330. For example, at least a portion of the first interlayer insulating layer 320 may be in contact with the etching stop layer 140. For example, at least a portion of the first interlayer insulating layer 320 may be in contact with the via 160.

For example, a vertical level of a lowermost surface 333b of the third portion 333 of the second interlayer insulating layer 330 may be lower than that of each of a lowermost surface 331b of the first portion 331 of the second interlayer insulating layer 330 and a lowermost surface 332b of the second portion 332 of the interlayer insulating layer 330. For example, the lowermost surface 332b of the second portion 332 of the second interlayer insulating layer 330 may have the same vertical level as that of the lowermost surface 331b of the first portion 331 of the second interlayer insulating layer 330. However, the present disclosure is not limited thereto.

Hereinafter, with reference to FIGS. 14 to 20, a method for manufacturing a semiconductor device according to still further some embodiments of the present disclosure is described. The following description focuses on differences thereof from the method for manufacturing the semiconductor device as shown in FIGS. 2 to 9.

FIGS. 15 to 20 are schematic cross-sectional views of intermediate structures corresponding to intermediate steps of an example method for manufacturing a semiconductor device according to one or more embodiments of the present disclosure.

Referring to FIG. 15, after the manufacturing process as shown in FIG. 2 and FIG. 3 has been performed, the first interlayer insulating layer 320 may be formed on the upper surface of the substrate 100. For example, the first interlayer insulating layer 320 may surround a sidewall of each of the first to fourth wiring patterns 111, 112, 113, and 114. Furthermore, the first interlayer insulating layer 320 may surround a portion of the sidewall of the mask pattern M. For example, the upper surface of the first interlayer insulating layer 320 may be concavely formed toward the upper surface of the substrate 100. For example, a vertical level of the uppermost surface of the first interlayer insulating layer 320 may be higher than a vertical level of the upper surface of each of the first to fourth wiring patterns 111, 112, 113, and 114.

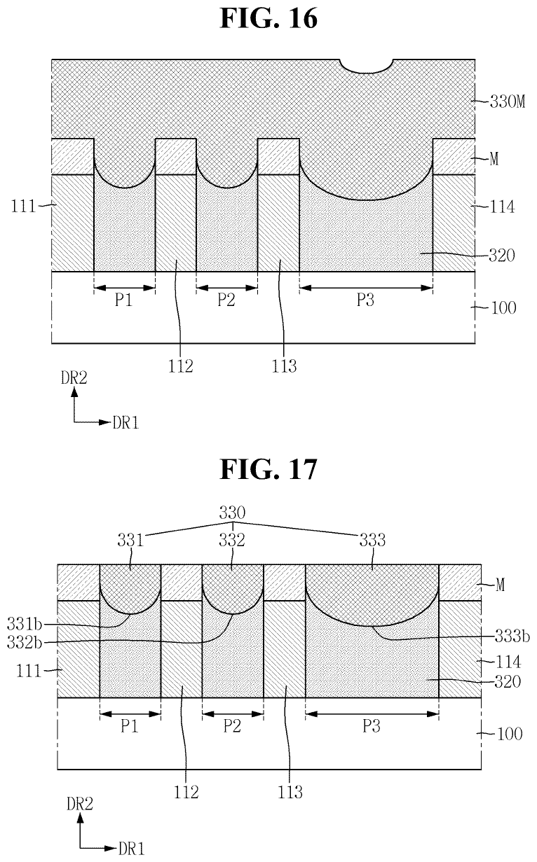

Referring to FIG. 16, an insulating material layer 330M may be formed on the upper surface of the first interlayer insulating layer 320. For example, the insulating material layer 330M may cover the sidewall and the upper surface of the mask pattern M. For example, the insulating material layer 330M does not contact each of the first to fourth wiring patterns 111, 112, 113, and 114.

Referring to FIG. 17, a portion of the insulating material layer (330M in FIG. 16) may be removed by performing a planarization process (e.g., CMP process). Through the planarization process (e.g., CMP process), the upper surface of the mask pattern M may be exposed. After the planarization process (e.g., CMP process) has been performed, the remaining insulating material layer (330M in FIG. 16) may be defined as the second interlayer insulating layer 330. For example, a portion of the insulating material layer (330M in FIG. 16) remaining between the first wiring pattern 111 and the second wiring pattern 112 may be defined as the first portion 331 of the second interlayer insulating layer 330. A portion of the insulating material layer (330M in FIG. 16) remaining between the second wiring pattern 112 and the third wiring pattern 113 may be defined as the second portion 332 of the second interlayer insulating layer 330. A portion of the insulating material layer (330M in FIG. 16) remaining between the third wiring pattern 113 and the fourth wiring pattern 114 may be defined as the third portion 333 of the second interlayer insulating layer 330. For example, the upper surface of the mask pattern M may be coplanar with the upper surface of each of the first to third portions 331, 332, and 333 of the second interlayer insulating layer 330, relative to the upper surface of the substrate 100.

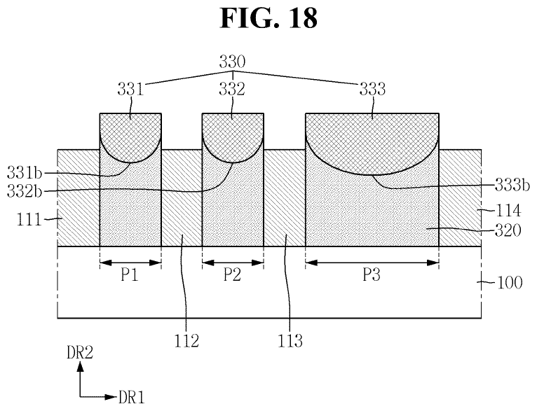

Referring to FIG. 18, the mask pattern (M in FIG. 17) may be removed. Thus, on the upper surface of each of the first to fourth wiring patterns 111, 112, 113, and 114, a portion of the side wall of each of the first to third portions 331, 332, 333 of the second interlayer insulating layer 330 may be exposed.

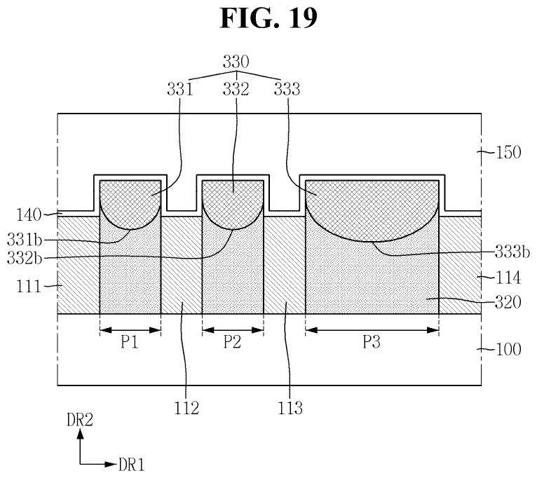

Referring to FIG. 19, the etching stop layer 140 may be formed on the upper surface of each of the first to fourth wiring patterns 111, 112, 113, and 114, the exposed sidewall and upper surface of each of the first to third portions 331, 332, and 333 of the second interlayer insulating layer 330, and an exposed upper sidewall of the first interlayer insulating layer 320. For example, the etching stop layer 140 may be formed conformally. Subsequently, the third interlayer insulating layer 150 may be formed on the upper surface of the etching stop layer 140.

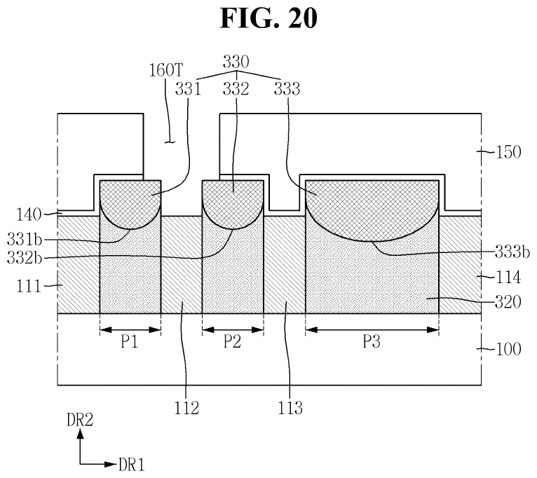

Referring to FIG. 20, the via trench 160T penetrating (i.e., extending in) the third interlayer insulating layer 150 and the etching stop layer 140 in the vertical direction DR2 may be formed on the upper surface of the second wiring pattern 112. For example, each of the upper surface of the second wiring pattern 112, the sidewall of the first portion 331 of the second interlayer insulating layer 330, the sidewall of the second portion 332 of the second interlayer insulating layer 330, and a portion of the sidewall of the first interlayer insulating layer 320 may be exposed through the via trench 160T. Furthermore, each of the upper surface of the first portion 331 of the second interlayer insulating layer 330 and a portion of the upper surface of the second portion 332 of the second interlayer insulating layer 330 may be exposed through the via trench 160T.

Referring to FIG. 14, the via 160 may be formed inside the via trench (160T in FIG. 20). The via 160 may contact the upper surface of the second wiring pattern 112. Furthermore, the via 160 may contact each of a sidewall of the first portion 331 of the second interlayer insulating layer 330 and a sidewall of the second portion 332 of the second interlayer insulating layer 330. Furthermore, the via 160 may contact a portion of the side wall of the first interlayer insulating layer 320. Furthermore, the via 160 may contact each of a portion of the upper surface of the first portion 331 of the second interlayer insulating layer 330 and a portion of the upper surface of the second portion 332 of the second interlayer insulating layer 330. Through this manufacturing process, the semiconductor device as shown in FIG. 14 may be manufactured.

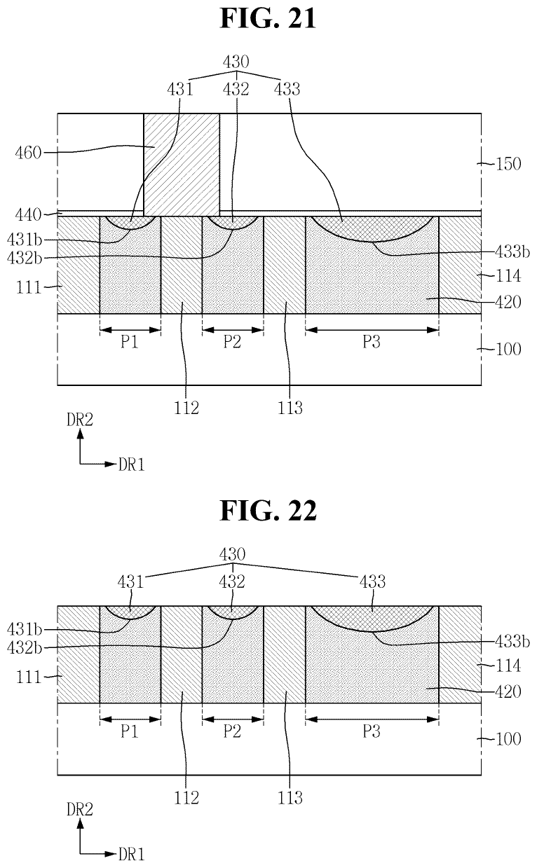

Hereinafter, with reference to FIG. 21, a semiconductor device according to one or more embodiments of the present disclosure is described. The following description focuses on differences thereof from the semiconductor device as shown in FIG. 1.

FIG. 21 is a schematic cross-sectional view illustrating a semiconductor device according to one or more embodiments of the present disclosure.

Referring to FIG. 21, in the semiconductor device according to one or more embodiments of the present disclosure, the upper surface of a second interlayer insulating layer 430 may be coplanar with the upper surface of each of the first to fourth wiring patterns 111, 112, 113, and 114, relative to the upper surface of the substrate 100. Furthermore, the second interlayer insulating layer 430 may be spaced apart from a sidewall of each of the first to fourth wiring patterns 111, 112, 113, and 114 in the horizontal direction DR1. That is, the second interlayer insulating layer 430 does not contact a sidewall of each of the first to fourth wiring patterns 111, 112, 113, and 114.

For example, the second interlayer insulating layer 430 may include first to third portions 431, 432, and 433. The first portion 431 of the second interlayer insulating layer 430 may be disposed between the first wiring pattern 111 and the second wiring pattern 112. The second portion 432 of the second interlayer insulating layer 430 may be disposed between the second wiring pattern 112 and the third wiring pattern 113. The third portion 433 of the second interlayer insulating layer 430 may be disposed between the third wiring pattern 113 and the fourth wiring pattern 114. For example, an upper surface of each of the first to third portions 431, 432, and 433 of the second interlayer insulating layer 430 may be coplanar with the upper surface of each of the first to fourth wiring patterns 111, 112, 113, and 114 relative to the upper surface of the substrate 100.

For example, the uppermost surface of the first interlayer insulating layer 420 may be coplanar with the upper surface of each of the first to fourth wiring patterns 111, 112, 113, and 114. Furthermore, the uppermost surface of the first interlayer insulating layer 420 may be coplanar with the upper surface of the second interlayer insulating layer 430. For example, at least a portion of the first interlayer insulating layer 420 may be disposed between each of the first to fourth wiring patterns 111, 112, 113, and 114 and the second interlayer insulating layer 430. For example, the uppermost surface of the first interlayer insulating layer 420 may contact an etching stop layer 440. For example, the uppermost surface of the first interlayer insulating layer 420 may contact a via 460.

For example, the etching stop layer 440 may be in contact with the upper surface of each of the first wiring pattern 111, the third wiring pattern 113, the fourth wiring pattern 114, and the second interlayer insulating layer 430. For example, the etching stop layer 440 does not contact the sidewall of the second interlayer insulating layer 430. For example, the via 460 may penetrate (i.e., extend in) the third interlayer insulating layer 150 and the etching stop layer 440 in the vertical direction DR2 so as to contact the second wiring pattern 112. For example, the lower surface of the via 460 may be in contact with each of the upper surface of the second wiring pattern 112, the uppermost surface of the first interlayer insulating layer 420, the upper surface of the first portion 431 of the second interlayer insulating layer 430, and the upper surface of the second portion 432 of the second interlayer insulating layer 430. For example, the via 460 does not contact a sidewall of each of the first portion 431 of the second interlayer insulating layer 430 and a sidewall of the second portion 432 of the second interlayer insulating layer 430.

For example, a vertical level of a lowermost surface 433b of the third portion 433 of the second interlayer insulating layer 430 may be lower than that of each of a lowermost surface 431b of the first portion 431 of the second interlayer insulating layer 430 and a lowermost surface 432b of the second portion 432 of the second interlayer insulating layer 430, relative to the upper surface of the substrate 100. For example, the vertical level of the lowermost surface 432b of the second portion 432 of the second interlayer insulating layer 430 may be equal to that of the lowermost surface 431b of the first portion 431 of the second interlayer insulating layer 430. However, the present disclosure is not limited thereto.

Hereinafter, with reference to FIGS. 21 to 24, a method for manufacturing a semiconductor device according to one or more embodiments of the present disclosure is described. The following description focuses on differences thereof from the methods for manufacturing the semiconductor devices as shown in FIG. 2, FIG. 3, and FIG. 15 to FIG. 20.

FIGS. 22 to 24 are schematic cross-sectional views of intermediate structures corresponding to intermediate steps of an example method for manufacturing a semiconductor device according to one or more embodiments of the present disclosure.

Referring to FIG. 22, after the manufacturing process shown in FIG. 2, FIG. 3, FIG. 15, and FIG. 16 is performed, the planarization process (e.g., CMP process) may be performed to form a portion of the insulating material layer (330M in FIG. 16) and the mask. The mask pattern M in FIG. 16 may be removed.

Through the planarization process (e.g., CMP process), the upper surface of each of the first to fourth wiring patterns 111, 112, 113, and 114 may be exposed. After the planarization process (e.g., CMP process) has been performed, the remaining insulating material layer (330M in FIG. 16) may be defined as the second interlayer insulating layer 430.

For example, a portion of the insulating material layer (330M in FIG. 16) remaining between the first wiring pattern 111 and the second wiring pattern 112 may be defined as the first portion 431 of the second interlayer insulating layer 430. The portion of the insulating material layer (330M in FIG. 16) remaining between the second wiring pattern 112 and the third wiring pattern 113 may be defined as the second portion 432 of the second interlayer insulating layer 430. The portion of the insulating material layer (330M in FIG. 16) remaining between the third wiring pattern 113 and the fourth wiring pattern 114 may be defined as the third portion 433 of the second interlayer insulating layer 430. For example, the upper surface of each of the first to fourth wiring patterns 111, 112, 113, and 114 may be coplanar with the upper surface of each of the first to third portions 131, 132 and 133 of the second interlayer insulating layer 430 and the uppermost surface of the first interlayer insulating layer 420, relative to the upper surface of the substrate 100.

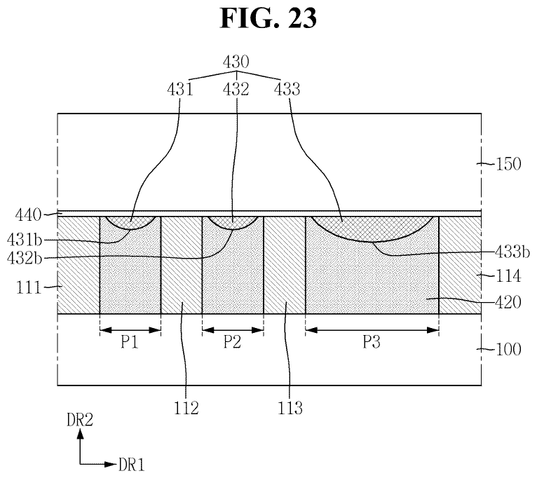

Referring to FIG. 23, an etching stop layer 440 and a third interlayer insulating layer 150 may be sequentially formed on the upper surface of each of the first to fourth wiring patterns 111, 112, 113, and 114, the uppermost surface of the first interlayer insulating layer 420, and the upper surface of each of the first to third portions 431, 432, and 433 of the second interlayer insulating layer 430.

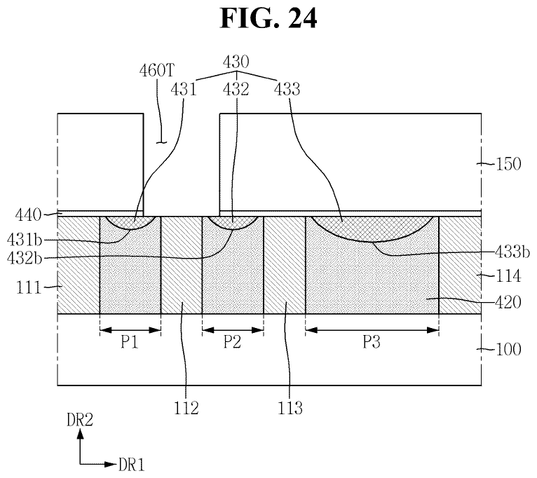

Referring to FIG. 24, a via trench 460T penetrating (i.e., extending in) the third interlayer insulating layer 150 and the etching stop layer 440 in the vertical direction DR2 may be formed on the upper surface of the second wiring pattern 112. For example, each of the upper surface of the second wiring pattern 112, a portion of the uppermost surface of the first interlayer insulating layer 420, a portion of the upper surface of the first portion 431 of the second interlayer insulating layer 430, and a portion of the upper surface of the second portion 432 of the second interlayer insulating layer 430 may be exposed through the via trench 460T.

Referring to FIG. 21, the via 460 may be formed inside the via trench 460T in FIG. 24. The via 460 may contact the upper surface of the second wiring pattern 112. Furthermore, the via 460 may contact each of a portion of the uppermost surface of the first interlayer insulating layer 420, a portion of the uppermost surface of the first portion 431 of the second interlayer insulating layer 430, and a portion of the upper surface of the second portion 432 of the second interlayer insulating layer 430. Through this manufacturing process, the semiconductor device as shown in FIG. 21 may be manufactured.

Although embodiments of the present disclosure have been described with reference to the accompanying drawings, the present disclosure is not limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor device, comprising:
a substrate;
a first wiring pattern on an upper surface of the substrate;
a second wiring pattern on the upper surface of the substrate, the second wiring pattern spaced apart from the first wiring pattern in a horizontal direction parallel to the upper surface of the substrate;
a first interlayer insulating layer extending around a sidewall of each of the first and second wiring patterns on the upper surface of the substrate, the first interlayer insulating layer including a first material having a first dielectric constant;
a second interlayer insulating layer in contact with an upper surface of the first interlayer insulating layer, at least a portion of the second interlayer insulating layer at least partially overlapping each of the first and second wiring patterns in the horizontal direction, the second interlayer insulating layer including a second material having a second dielectric constant greater than the first dielectric constant;
a third interlayer insulating layer on an upper surface of the second interlayer insulating layer; and
a via extending in the third interlayer insulating layer in a vertical direction perpendicular to the upper surface of the substrate, the via connected to the first wiring pattern,
wherein each of the first and second interlayer insulating layers is non-overlapping with respect to each of the first and second wiring patterns in the vertical direction.

2. The semiconductor device of claim 1, wherein the third interlayer insulating layer includes a third material having a third dielectric constant lower than the second dielectric constant.

3. The semiconductor device of claim 1, wherein at least a portion of the via is in contact with the upper surface of the second interlayer insulating layer.

4. The semiconductor device of claim 1, further comprising an etching stop layer between the third interlayer insulating layer and each of an upper surface of the second wiring pattern and the upper surface of the second interlayer insulating layer.

5. The semiconductor device of claim 1, further comprising a third wiring pattern on the upper surface of the substrate, the third wiring pattern spaced apart from the second wiring pattern in the horizontal direction,
wherein a pitch between the second wiring pattern and the third wiring pattern in the horizontal direction is greater than a pitch between the first wiring pattern and the second wiring pattern in the horizontal direction.

6. The semiconductor device of claim 5, wherein the second interlayer insulating layer includes a first portion between the first wiring pattern and the second wiring pattern, and a second portion between the second wiring pattern and the third wiring pattern, and
wherein a lowermost surface of the second portion of the second interlayer insulating layer is lower than a lowermost surface of the first portion of the second interlayer insulating layer, relative to the upper surface of the substrate as a reference layer.

7. The semiconductor device of claim 1, wherein the upper surface of the second interlayer insulating layer is higher than an upper surface of each of the first and second wiring patterns, relative to the upper surface of the substrate as a reference layer.

8. The semiconductor device of claim 1, wherein the upper surface of the second interlayer insulating layer is coplanar with an upper surface of each of the first and second wiring patterns.

9. The semiconductor device of claim 1, wherein the second interlayer insulating layer is spaced apart from a sidewall of each of the first and second wiring patterns in the horizontal direction.

10. The semiconductor device of claim 9, wherein at least a portion of the first interlayer insulating layer is between the second interlayer insulating layer and each of the first and second wiring patterns.

11. The semiconductor device of claim 10, wherein an uppermost surface of the first interlayer insulating layer is coplanar with the upper surface of the second interlayer insulating layer.

12. The semiconductor device of claim 1, wherein the second material included in the second interlayer insulating layer is different from the first material included in the first interlayer insulating layer.

13. A semiconductor device, comprising:
a substrate;
first, second, and third wiring patterns sequentially spaced apart from each other on an upper surface of the substrate in a horizontal direction parallel to the upper surface of the substrate;
a first interlayer insulating layer extending around a sidewall of each of the first, second, and third wiring patterns on the upper surface of the substrate, the first interlayer insulating layer including a first material having a first dielectric constant;
a second interlayer insulating layer in contact with an upper surface of the first interlayer insulating layer, at least a portion of the second interlayer insulating layer at least partially overlapping each of the first, second, and third wiring patterns in the horizontal direction, the second interlayer insulating layer including a second material having a second dielectric constant greater than the first dielectric constant, the second interlayer insulating layer including a first portion between the first wiring pattern and the second wiring pattern, and a second portion between the second wiring pattern and the third wiring pattern;
a third interlayer insulating layer on an upper surface of the second interlayer insulating layer, the third interlayer insulating layer including a third material having a third dielectric constant lower than the second dielectric constant; and
an etching stop layer between the third interlayer insulating layer and each of an upper surface of the second wiring pattern, an upper surface of the third wiring pattern and the upper surface of the second interlayer insulating layer,
wherein a pitch between the second wiring pattern and the third wiring pattern in the horizontal direction is greater than a pitch between the first wiring pattern and the second wiring pattern in the horizontal direction, and
wherein a lowermost surface of the second portion of the second interlayer insulating layer is lower than a lowermost surface of the first portion of the second interlayer insulating layer relative to the upper surface of the substrate as a reference layer.

14. The semiconductor device of claim 13, wherein each of the first and second interlayer insulating layers is non-overlapping with respect to each of the first, second, and third wiring patterns in a vertical direction perpendicular to the upper surface of the substrate.

15. The semiconductor device of claim 13, wherein each of the first material included in the first interlayer insulating layer and the second material included in the second interlayer insulating layer includes silicon oxycarbide (SiOC), and
wherein a concentration of carbon (C) in the second material is lower than a concentration of carbon (C) in the first material.

16. The semiconductor device of claim 13, wherein a density of the second interlayer insulating layer is greater than a density of the first interlayer insulating layer.

17. The semiconductor device of claim 13, wherein the first dielectric constant ranges from about 1.8 to 3.1, and the second dielectric constant ranges from about 3.1 to 8.

18. The semiconductor device of claim 13, wherein the second interlayer insulating layer is in contact with a sidewall of each of the first, second, and third wiring patterns.

19. The semiconductor device of claim 13, wherein at least a portion of the third interlayer insulating layer is between the first portion of the second interlayer insulating layer and the second portion of the second interlayer insulating layer.

20. A semiconductor device, comprising:
a substrate;
first second, and third wiring patterns sequentially spaced apart from each other in a horizontal direction, parallel to an upper surface of the substrate, on the upper surface of the substrate;
a first interlayer insulating layer extending around a sidewall of each of the first, second, and third wiring patterns on the upper surface of the substrate, the first interlayer insulating layer including a first material having a first dielectric constant;
a second interlayer insulating layer in contact with an upper surface of the first interlayer insulating layer, at least a portion of the second interlayer insulating layer at least partially overlapping each of the first, second, and third wiring patterns in the horizontal direction, an upper surface of the second interlayer insulating layer being higher than an upper surface of each of the first, second, and third wiring patterns relative to the upper surface of the substrate as a reference layer, the second interlayer insulating layer in contact with a sidewall of each of the first, second, and third wiring patterns, the second interlayer insulating layer including a second material having a second dielectric constant greater than the first dielectric constant, the second interlayer insulating layer including a first portion between the first wiring pattern and the second wiring pattern, and a second portion between the second wiring pattern and the third wiring pattern;
a third interlayer insulating layer on the upper surface of the second interlayer insulating layer, the third interlayer insulating layer including a third material having a third dielectric constant lower than the second dielectric constant;
an etching stop layer between the third interlayer insulating layer and each of the upper surface of the second wiring pattern, the upper surface of the third wiring pattern and the upper surface of the second interlayer insulating layer; and
a via extending in the third interlayer insulating layer and the etching stop layer in a vertical direction perpendicular to the upper surface of the substrate, the via connected to the first wiring pattern, at least a portion of the via in contact with the upper surface of the second interlayer insulating layer,
wherein each of the first and second interlayer insulating layers is non-overlapping with respect to each of the first, second, and third wiring patterns in the vertical direction,
wherein a pitch between the second wiring pattern and the third wiring pattern in the horizontal direction is greater than a pitch between the first wiring pattern and the second wiring pattern in the horizontal direction, and
wherein a lowermost surface of the second portion of the second interlayer insulating layer is lower than a lowermost surface of the first portion of the second interlayer insulating layer relative to the upper surface of the substrate.
